(19) United States
(12) Patent Application Publication
(10) Pub. No.: US 2008/0078745 A1
(43) Pub. Date: Apr. 3, 2008

(54) RF Coil Plasma Generation

(75) Inventors: Andrew Cordell, McKinney, TX (US); Guido Fridolin Verbeck, Plano, TX (US)

Correspondence Address: HAYNES AND BOONE, LLP, 901 Main Street, Suite 3100, Dallas, TX, 75202, US

(73) Assignee: ZYVEX CORPORATION, Richardson, TX (US)

(21) Appl. No.: 11/537,411

(22) Filed: Sep. 29, 2006

(51) Int. Cl. H01L 21/306; C23F 1/00

(52) U.S. Cl. 216/67; 156/345.48; 156/345.49; 156/345.24; 156/345.28

(57) ABSTRACT

Methods of operating a plasma chamber for use with an electron or ion beam apparatus. The method may comprise igniting a plasma in the plasma chamber by utilizing a first radio frequency (RF) power and a first plasma chamber pressure. The plasma may then be maintained by utilizing a second RF power and a second plasma chamber pressure, wherein the second RF power is substantially less than the first RF power and the second plasma chamber pressure is substantially greater than the first plasma chamber pressure.

### CROSS-REFERENCE TO RELATED APPLICATIONS

This application is related to commonly-assigned U.S. application Ser. No. ______, entitled “RF COIL PLASMA GENERATION,” Attorney Docket No. 34003.184, filed concurrently herewith.

### BACKGROUND

Low temperature plasmas of various ionized gases can be used to reactively etch or ash organic materials found on the surface of materials. Such plasma cleaning, etching or ashing has been used to clean and otherwise condition the interiors of large vacuum vessels, as well as to clean and etch semiconductor wafers and other bulk materials. For example, commercially-available RF or DC plasma, dry-ashing devices may be utilized for cleaning electron microscope components and specimens prior to specimen analysis. In such devices, glow discharge is used to produce ions that are then transformed oxygen radicals by subsequent reactions, and the radicals are fed from the plasma chamber in which they are generated, into the vacuum chamber where specimens are to be analyzed.

### BRIEF DESCRIPTION OF THE DRAWINGS

The present disclosure is best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a schematic view of apparatus according to one or more aspects of the present disclosure.

FIG. 2 is a schematic view of apparatus according to one or more aspects of the present disclosure.

FIG. 3 is a schematic view of apparatus according to one or more aspects of the present disclosure.

FIG. 4 is a schematic view of apparatus according to one or more aspects of the present disclosure.

FIG. 5 is a state diagram demonstrating one or more aspects of the present disclosure.

FIGS. 6A-6D are flow-chart diagrams each demonstrating one or more aspects of the present disclosure.

### DETAILED DESCRIPTION

It is to be understood that the following disclosure provides many different embodiments, or examples, for implementing different features of various embodiments. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

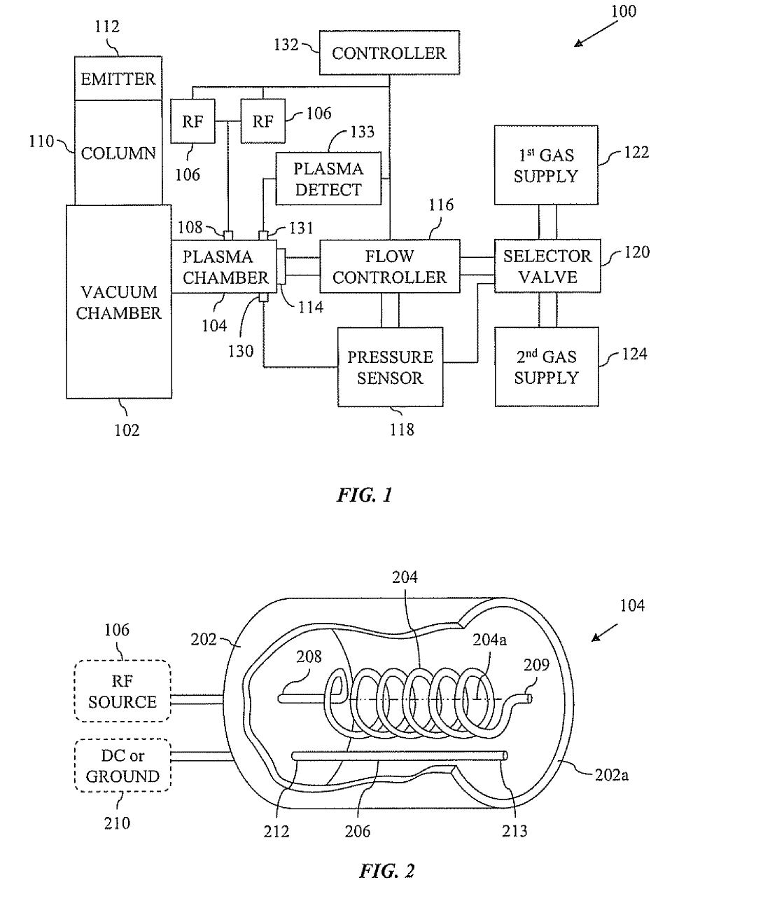

Referring to FIG. 1, illustrated is a block diagram of apparatus 100 according to one or more aspects of the present disclosure. Embodiments of apparatus 100 within the scope of the present disclosure may include each of the components shown in FIG. 1, multiple instances of one or more of the components shown in FIG. 1, and/or a subset of the components shown in FIG. 1, as well as other components not specifically described herein.

Apparatus 100 may include a vacuum chamber 102, a plasma chamber 104, and one or more RF power sources 106. The vacuum chamber 102 may be that of a scanning electron microscope (SEM) or other microscopy apparatus, and may be conventional or future-developed. However, the vacuum chamber 102 may be retrofitted to be configured to receive the plasma chamber 104 according to aspects of the present disclosure. The plasma chamber 104 may be coupled or integral to the vacuum chamber 102, and may also be of a conventional or future-developed nature, except as otherwise described herein. The plasma chamber 104 is configured to generate a plasma which feeds into the vacuum chamber 102 via one or more apertures between the plasma chamber 104 and the vacuum chamber 102, and/or other means. The one or more RF power sources 106 may be configured to deliver an RF signal to a coil within the plasma chamber 104 to ignite and maintain plasma generation within the plasma chamber 104. For example, apparatus 100 may include a conventional or future-developed electrical feedthrough 108 through which the electrical signal may be delivered from the one or more RF power sources 106 to the internal coil.

Apparatus 100 may also include one or more of a column 110 with an integral or attached emitter 112. The column 110 may be configured to steer and/or focus an electron beam, ion beam, and/or other beam. For example, the column 110 and/or emitter 112 may be that of an SEM or other microscopy apparatus, and may be conventional or future-developed.

Apparatus 100 may also include one or more of a gas inlet 114, a flow controller 116, a flow or pressure sensor 118, a selector valve 120, a first gas supply 122, and a second gas supply 124, each of which may be conventional and/or future-developed. The flow controller 116 may be or include a flow servo and/or other components configured to regulate gas flow from the selector valve 120 through the gas inlet 114 and into the plasma chamber 104. The flow controller 116 may be manually or automatically operable. The flow or pressure sensor 118 may be configured to monitor the flow rate, pressure and/or composition of plasma source gas through the flow controller 116.

The selector valve 120 is manually or automatically operable to select between the first gas supply 122 and the second gas supply 124. The first and second gas supplies 122, 124 may contain the same or different gas compositions to be utilized as plasma source gas. For example, the first gas supply 122 may contain an oxygen gas supply and the second gas supply 124 may contain an argon gas supply. Of course, other compositions are also within the scope of the present disclosure. The selector valve 120 and/or the flow controller 116 may be configured such that gas from only one of the gas supplies 122, 124 may flow into the plasma chamber 104 at a time, or may alternatively be configured to allow flow of various mixtures of gas from the gas supplies 122, 124 simultaneously.

Apparatus 100 may also include one or more sensors 130, 131 for detecting the presence of plasma within the plasma chamber 104 and/or for detecting a plasma concentration in the plasma chamber 104. The sensors 130, 131 may be conventional or future-developed, and may also or alternatively be configured to detect other conditions within the plasma chamber 104. For example, sensor 131 may be configured to detect current flow between the coil and the wall of plasma chamber 104, the signal from which may be transmitted to a plasma detect circuit 133 for generating a signal sent to the controller 132 to indicate existence and/or concentration of plasma within the chamber 104.

Apparatus 100 may also include a controller 132 (or multiple controllers hereafter referred to collectively as the controller 132). The controller 132 may be configured to send and/or receive information to/from the sensors 130, 131, one or more of the RF power sources 106, the flow controller 116, the flow sensor 118, and/or the selector valve 120, and/or other components of the apparatus 100. The controller 132 may be configured to operate the plasma chamber 104 and the RF power sources 106 in an ignition state and a steady state.

For example, the controller 132 may be configured to increase the pressure of the plasma chamber 104 and/or decrease the output from one or more of the RF power sources 106 when transitioning from the ignition state to the steady state. The controller 132 may also or alternatively be configured to transition operation of the plasma chamber 104 and/or one or more of the RF power sources 106 between the ignition state and the steady state in response to the expiration of a predetermined time period. The controller 132 may also or alternatively be configured to transition operation of the plasma chamber 104 and/or one or more of the RF power sources 106 between the ignition state and the steady state in response to detection of plasma within the plasma chamber 104 via sensor 130 and/or 131. The controller 132 may also or alternatively be configured to transition operation of the plasma chamber 104 and/or one or more of the power sources 106 between the steady state and the ignition state in response to a plasma level within the plasma chamber 104 falling below a minimum plasma level, as possibly detected by sensor 130 and/or 131.

Referring to FIG. 2, illustrated is a perspective view of at least a portion of the plasma chamber 104 shown in FIG. 1, in which a section of the plasma chamber's wall 202 has been removed for illustrative purposes. The plasma chamber 104 includes a coil 204 and a conductive member 206, as described below. Although not illustrated, the plasma chamber 104 also includes an interface for coupling to the vacuum chamber 102 described above and shown in FIG. 1. Alternatively, the plasma chamber 104 is integral to the vacuum chamber 102. The plasma chamber 104 may be substantially cylindrical in shape, having an outer diameter ranging between about 30 mm and about 150 mm, an inner diameter ranging between about 25 mm and about 140 mm, and a length ranging between about 15 mm and about 150 mm. As shown in FIG. 2, an end 202a of the plasma chamber 104 may be open or otherwise have an aperture and/or other means through which plasma may feed into the vacuum chamber 102.

The coil 204 comprises a conductive wire or other material that has been formed into a number of turns. For example, in the illustrated embodiment, the coil 204 includes about 5½ turns. In other embodiments within the scope of the present disclosure, the coil 204 may have a number of turns ranging between about 4 and about 200. The coil 204 may substantially comprise aluminum, copper, gold, or alloys thereof, among other compositions. The coil 204 may also include an outer coating of dielectric material and/or other materials. The outer diameter of the coil 204 may range between about 20 mm and about 130 mm, and the length of the coil 204 may range between about 15 mm and about 150 mm. The thickness or gauge of the wire or other material forming the coil 204 may range between about 0.001″ and about 0.25″.

One end 208 of the coil 204 is connected, at least indirectly, to one or more of the RF sources 106 described above. The other end 209 of the coil 204 may not be electrically connected to anything, such that the coil 204 may be electrically open-ended. The coil 204 may also be electrically isolated from the plasma chamber wall 202 and/or the remainder of the plasma chamber 104. For example, an electrical feedthrough may be employed to connect the coil 204 to the RF source 106 through the chamber wall 202. Such electrical feedthrough may also be utilized to set the position of the coil 204 within the plasma chamber 104.

The conductive member 206 comprises a conductive wire or other material that is positioned between the coil 204 and the plasma chamber wall 202. The conductive member 206 may be positioned substantially parallel to the central axis 204a of the coil 204 and/or the plasma chamber wall 202. The conductive member 206 may alternatively be omitted, such as where the internal surface of the chamber wall 202, or a portion thereof, performs the function of the conductive member 206. That is, the conductive member 206 may be an alternate ground to the chamber wall 202. For example, if a controlled, reduced plasma is needed, the conductive member 206 may be employed, because it may become difficult to reduce the production of needed radicals with a single coil under certain RF power constraints. Thus, the conductive member 206 may optionally be included to better lower the radical production.

The conductive member 206 may substantially comprise aluminum, copper, gold, or alloys thereof, among other compositions. The conductive member 206 may also include an outer coating of dielectric material and/or other materials. The length of the conductive member 206 may range between about 15 mm and about 150 mm, and the thickness or gauge of the wire or other material forming the conductive member 206 may range between about 0.001″ and about 0.25″.

One end 212 of the conductive member 206 may be connected, at least indirectly, to a DC or ground potential. The other end 213 of the conductive member 206 may not be electrically connected to anything, such that the conductive member 206 may be electrically open-ended. The conductive member 206 may electrically isolated from the plasma chamber wall 202 and/or the remainder of the plasma chamber 104. For example, an electrical feedthrough may be employed to connect the conductive member 206 to the DC or ground potential 210 through the chamber wall 202. Such electrical feedthrough may also be utilized to set the position of the conductive member 206 within the plasma chamber 104. The conductor may be laterally separated from the outer perimeter of the coil 204 by a distance ranging between about 0.25″ and about 10″, and/or by a distance ranging between about 10% and about 100% of the outer diameter of the coil 204.

Referring to FIG. 3, illustrated is a schematic diagram of at least a portion of the plasma chamber 104 shown in FIGS. 1 and 2 demonstrating one or more aspects of the present disclosure. As in the embodiment shown in FIG. 2, the plasma chamber 104 includes the open-ended coil 204 and the grounded or DC-biased conductive member 206 (shown as being grounded in FIG. 3).

In the embodiment illustrated in FIG. 3, the coil 204 includes about 7½ turns. The thickness or gauge of the material utilized to form the coil 204 is described above. The gap between each neighboring pair of turns may range between 0 and about 12 mm. For example, the gap may range between about 0 and about 4 mm. The pitch P may be less than about 150% of the wire thickness. For example, the pitch P may be about 110% of the wire thickness.

The radius R of one or more turns of the coil 204 may range between about 5 mm and about 65 mm. In the embodiment illustrated in FIG. 3, each turn of the coil 204 has a substantially similar radius R, although in other embodiments one or more turns of the coil 204 may have a different radius R relative to other turns of the coil 204.

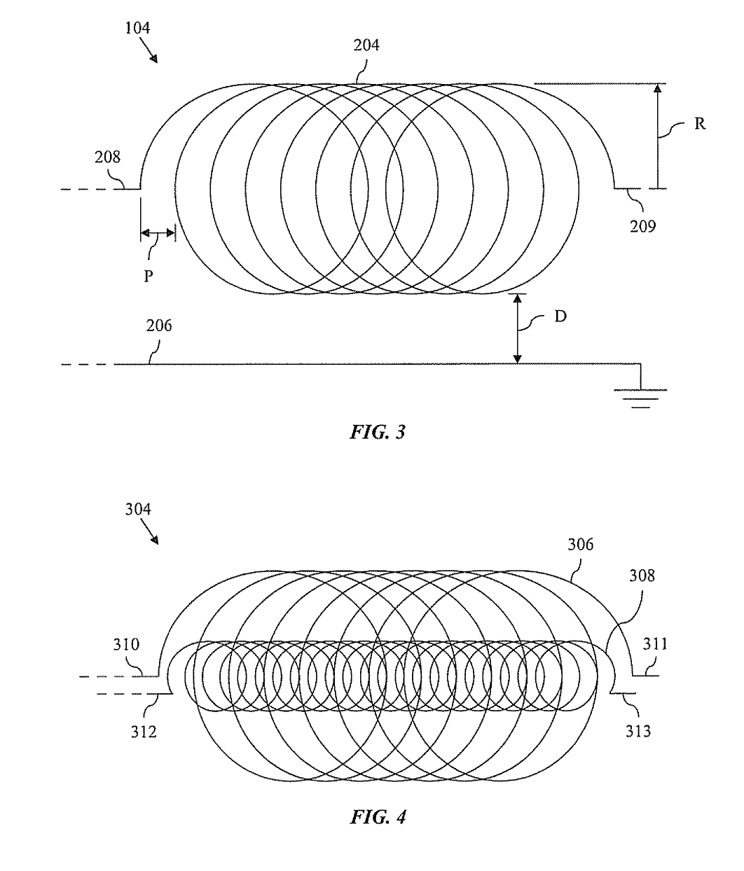

Referring to FIG. 4, illustrated is a schematic view of another embodiment of at least a portion of the internal components of the plasma chamber 104 shown in FIGS. 1-3, herein designated by the reference numeral 304. The plasma chamber 304 may be utilized in substantially the same manner as the plasma chamber 104 shown in FIGS. 1-3, and may otherwise be substantially similar in composition, manufacture, and geometry to the plasma chamber 104, except as described below.

The plasma chamber 304 includes an outer coil 306 and an inner coil 308. The outer coil 306 may be substantially similar in composition, manufacture, and geometry to the coil 204 described above and shown in FIGS. 2 and 3, For example, the outer coil 306 may include an end 310 that is coupled, at least indirectly, to an RF power source, such as the RE source 106 shown in FIGS. 1 and 2. Another end 311 of the outer coil 306 may be open. The outer coil 306 may have a number of turns ranging between about 4 and about 200, an outer diameter ranging between about 20 mm and about 130 mm, and a length ranging between about 15 mm and about 150 mm, where the gaps between each pair of neighboring turns may range between about 0 and about 12 mm.

The inner coil 308 may be positioned substantially coaxially within the outer coil, and may be substantially similar in composition and manufacture to the outer coil 306. The outer diameter of the inner coil 308 may range between about 10 mm and about 100 mm, and its length may range between about 15 mm and about 150 mm. The inner coil 308 may have a number of turns ranging between about 5 and about 500.

The ratio of the outer diameter of the outer coil 306 to the outer diameter of the inner coil 308 may range between about 1.1 and about 7, The ratio of the number of turns included in the outer coil 306 to the number of turns included in the inner coil 308 may range between about 1.1 and about 10. The ratio of the length of the outer coil 306 to the length of the inner coil 308 may range between about 1 and about 0.5.

An end 312 of the inner coil 308 may be electrically coupled, at least indirectly, to an RF power source, such as the RF power source 106 shown in FIGS. 1 and 2, whereas the other end 313 may be open. The outer coil 306 and the inner coil 308 may be connected to the same RF source or to different RF sources, such that each of the coils 306, 308 may be driven independently, and may be driven simultaneously with the same or different RF sources.

The ends 311, 313 of the outer and inner coils 306, 308, respectively, may each be electrically open. In embodiments in which both of the outer and inner coils 306, 308 are included within the plasma chamber 304, the conductive member 206 shown in FIGS. 2 and 3 may not be included. However, the plasma chamber 304 itself (such as the plasma chamber wall 202 shown in FIG. 2) may be electrically grounded, whether or not the conductor member 206 is included in the plasma chamber, an whether or not a single coil 204 or dual-coils 206/208 are included in the plasma chamber. The same holds true for the plasma chamber 104 shown in FIGS. 1-3.

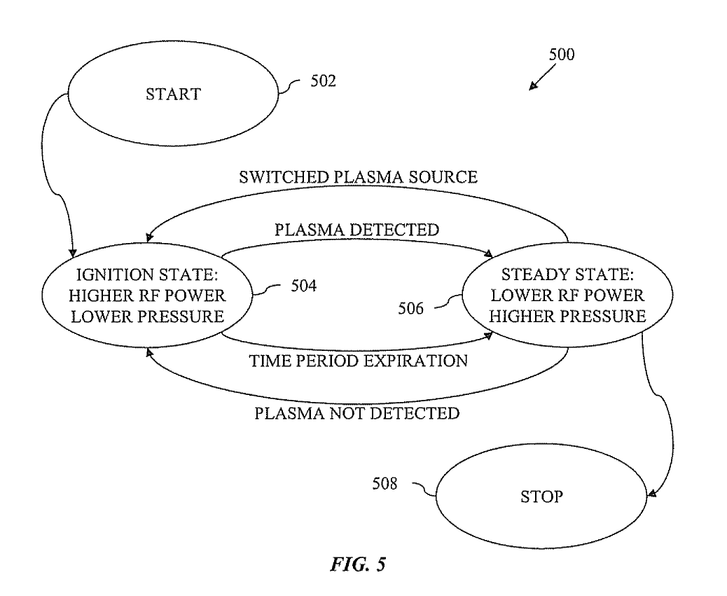

Referring to FIG. 5, illustrated is a state diagram 500 demonstrating one or more aspects of the present disclosure. The state diagram 500 demonstrates one or more operational aspects of the plasma chamber 104 shown in FIGS. 1 and 2, the apparatus 100 shown in FIG. 1, and/or the coils 204, 304, 306 and 308 shown in FIGS. 1-4.

Operation may begin in a START state 502. Operation may then transition to an IGNITION state 504 after, for example, a start-up procedure is executed, among other possible transition-triggering events. The IGNITION state 504 is utilized to ignite a plasma in the plasma chamber (such as the plasma chamber 104 or 304 shown in FIGS. 1-4). For example, an ignition RF power level and an ignition pressure level may be utilized in the IGNITION state 504.

Operation may then transition to a STEADY state 506 upon the occurrence of the appropriate transition-triggering event. For example, the plasma chamber may be monitored to detect the presence or level of plasma. If plasma is detected when the IGNITION state 504 is active, operation may transition to the STEADY state 506. Alternatively, or additionally, the IGNITION state 504 may only be operational for a predetermined period of time. Upon the expiration of such time period, operation may transition to the STEADY state 506. For example, the predetermined time period may range between about 5 seconds and about 30 seconds, and may be user selectable and/or preprogrammed by the manufacturer. In an exemplary embodiment, the predetermined time period may be about 10 seconds.

The STEADY state 506 is utilized to maintain plasma generation within the plasma chamber. For example, a steady state RF power level and a steady state pressure level may be maintained in the STEADY state 506. The steady state RF power level may be less than the ignition RF power level, whereas the steady state pressure level may be greater than the ignition pressure level. The ignition RF power level may range between about 10 W and about 20 W, whereas the steady state RE power level may range between about 1 W and about 10 W. The ignition pressure level may range between about 10 mT and about 600 mT, whereas the steady state pressure level may range between about 300 mT and about 1000 mT. The steady state RF power and pressure levels may be configured such that oxygen radicals and/or other radicals are generated in the plasma chamber, such that the radicals may feed into the vacuum chamber for cleaning and/or other purposes.

Operation in the STEADY state 506 may continue until the occurrence of the appropriate transition-triggering event. For example, one such event may be when the plasma source gas is altered, such as by switching between the first and second gas supplies 122, 124 shown in FIG. 1, or by altering the composition of a mixture of gas being delivered from the first and second gas supplies simultaneously. Either of such events, among others, may trigger operation to transition back to the IGNITION state 504. Another exemplary event that may trigger the transition from the STEADY state 506 to the IGNITION state 504 is the detection of plasma in the plasma chamber dropping below a threshold concentration, or the lack of plasma existence in the plasma chamber. In either case, operation transitions back to the IGNITION state 504 so that plasma ignition can be repeated, at which time operation may once again transition to the STEADY state 506. Operation may also transition from the STEADY state 506 to a STOP state 508 upon the occurrence of the appropriate transition-triggering event, such as the receipt of user-input indicating that operation is to be halted.

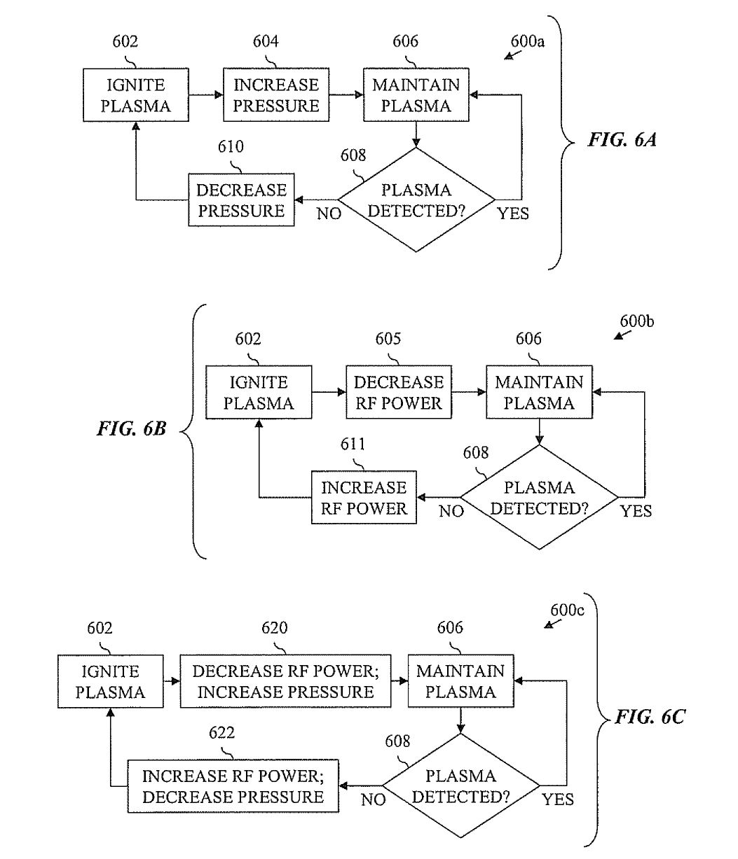

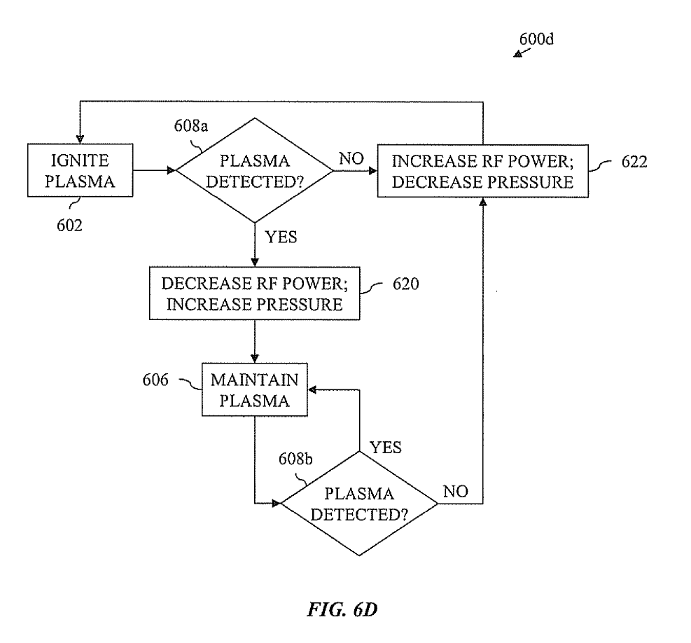

Referring to FIGS. 6A-6D, illustrated are various embodiments of methods operable in conjunction with the apparatus described above and shown in FIGS. 1-5. In FIG. 6A, method 600a includes a step 602 in which a plasma is ignited, as described above. After the plasma is ignited, the plasma chamber pressure is increased in a step 604 to a steady state plasma generation chamber pressure. The plasma generation is then maintained during a step 606 until, as determined by decisional step 608, plasma is no longer detected. That is, if plasma is continually detected during step 608, then the step 606 is repeated. However, if it is determined during decisional step 608 that plasma is no longer detected, or that plasma concentration has dropped below a threshold value, then the pressure is decreased in a step 610, and step 602 is repeated to re-ignite the plasma.

In FIG. 6B, method 600b includes step 602 in which plasma is ignited, as described above. After the plasma is ignited, the RF power is decreased in a step 605 to a steady state plasma generation RF power. The plasma generation is then maintained during step 606 until, as determined by decisional step 608, plasma is no longer detected. That is, if plasma is continually detected during step 608, then the step 606 is repeated. However, if it is determined during decisional step 608 that plasma is no longer detected, or that plasma concentration has dropped below a threshold value, then the RF power is increased in a step 611, and step 602 is repeated to re-ignite the plasma.

In FIG. 6C, method 600c includes step 602 in which plasma is ignited, as described above. After the plasma is ignited, the RF power is decreased to a steady state plasma generation RF power, and the plasma chamber pressure is increased to a steady state plasma generation chamber pressure, in a step 620. The plasma generation is then maintained during step 606 until, as determined by decisional step 608, plasma is no longer detected. That is, if plasma is continually detected during step 608, then the step 606 is repeated. However, if it is determined during decisional step 608 that plasma is no longer detected, or that plasma concentration has dropped below a threshold value, then the RF power is increased and the chamber pressure is decreased in a step 622, and step 602 is repeated to re-ignite the plasma.

In FIG. 6D, method 600d includes step 602 in which plasma is ignited, as described above. After plasma ignition is attempted, decisional step 608a is performed determine whether plasma has successfully been ignited. If plasma has not been ignited, or if plasma concentration is not at an acceptable level, then the RF power is increased and the plasma chamber pressure is decreased in step 622. Plasma ignition is then attempted again in step 602. This iterative process may be repeated until plasma is significantly ignited, and perhaps generated to at least a predetermined concentration, as determined by decisional step 608a.

Once plasma has been adequately ignited, as determined by decisional step 608a, the RF power is decreased and the plasma chamber pressure is increased in step 620. Thereafter, plasma is maintained in step 606. However, the plasma concentration level may be periodically, continuously, or otherwise monitored. If sufficient plasma is detected, as determined by decisional step 608b, then step 606 is repeated and the plasma generation is maintained. However, if sufficient plasma is not detected, as determined by decisional step 608b, then the RF power is increased and the plasma chamber pressure is decreased as step 622 is repeated, and then plasma re-ignition is attempted as step 602 is repeated.

In each of the above-described methods 600a-600d, and others within the scope of the present disclosure, the plasma chamber pressure during plasma ignition and/or plasma generation (steady state) may range between about 10 mT and about 10 T. In an exemplary embodiment, the plasma chamber pressure during plasma ignition is about 100 mT and the plasma chamber pressure during steady state plasma generation is about 600 mT, or the plasma chamber pressure during steady state plasma generation may be about 600% greater than the plasma chamber pressure during plasma ignition.

Additionally, in each of the above-described methods 600a-600d, and others within the scope of the present disclosure, the RE power during plasma ignition and/or plasma generation (steady state) may range between about 5 W and about 20 W. In an exemplary embodiment, the RF power during plasma ignition is about 20 W and the RF power during steady state plasma generation is about 10 W, or the RE power during steady state may otherwise be about 50% less than the RF power during the plasma ignition.

Moreover, in each of the above-described methods 600a-600d, and others within the scope of the present disclosure, the RF frequency during plasma ignition and/or plasma generation (steady state) may range between about 1 MHz and about 1 Hz. In an exemplary embodiment, the RF frequency during plasma ignition and steady state plasma generation is about 13.56 MHz.

It should be evident from the description above that the present disclosure introduces an apparatus comprising a plasma chamber, a radio frequency (RF) power source, and a coil centrally disposed in the plasma chamber. The plasma chamber is configured to generate plasma that feeds a vacuum chamber adjacent the plasma chamber, and a first end of the coil is electrically coupled to the RF power source while a second end of the coil is electrically open.

A method of manufacturing an apparatus is also introduced in the present disclosure, and includes disposing a coil centrally in a plasma chamber, wherein a first end of the coil is electrically open, and wherein the plasma chamber is configured to generate plasma that feeds into a vacuum chamber adjacent the plasma chamber. A radio frequency (RF) power source is then coupled to a second end of the coil.

Additional apparatus introduced in the present disclosure comprises a vacuum chamber, an emitter configured to emit a beam of at least one of ions and electrons into the vacuum chamber, and a plasma chamber coupled to the vacuum chamber. Such apparatus also includes means for supplying a plasma source gas into the plasma chamber, a radio frequency (RF) power source, and a coil located in a substantially central portion of the plasma chamber, wherein a first end of the coil is electrically coupled to the RF power source and a second end of the coil is electrically open.

Also introduced in the present disclosure is a method of operating a plasma chamber for use with an electron or ion beam apparatus. The method may comprise igniting a plasma in the plasma chamber by utilizing a first radio frequency (RF) power and a first plasma chamber pressure. The plasma may then be maintained by utilizing a second RF power and a second plasma chamber pressure, wherein the second RF power is substantially less than the first RF power and the second plasma chamber pressure is substantially greater than the first plasma chamber pressure.

Another method introduced in the present disclosure comprises transitioning a plasma chamber to a steady state when a first event occurs, and transitioning the chamber to an ignition state when a second event occurs. In such a method, the ignition state employs a greater RF power than the steady state, and the steady state employs a greater chamber pressure than the ignition state.

A system introduced in the present disclosure comprises a plasma chamber, a radio frequency (RF) power source coupled to a magnetic plasma igniting means that is disposed within the plasma chamber, and a controller configured to operate the plasma chamber and the RF power source in an ignition state and a steady state, including increasing the plasma chamber's pressure and decreasing the RF power source's output when transitioning from the ignition state to the steady state.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A method of operating a plasma chamber for use with an electron or ion beam apparatus, comprising:
igniting a plasma in the plasma chamber by utilizing a first radio frequency (RF) power and a first plasma chamber pressure; and
maintaining the plasma by utilizing a second RF power and a second plasma chamber pressure, wherein the second RF power is substantially less than the first RF power and the second plasma chamber pressure is substantially greater than the first plasma chamber pressure.

2. The method of claim 1 wherein the second RF power is about 50% less than the first RF power.

3. The method of claim 1 wherein the first RF power is about 20 W and the second RF power is about 10 W.

4. The method of claim 1 wherein the second plasma chamber pressure is about 600% greater than the first plasma chamber pressure.

5. The method of claim 1 wherein the first plasma chamber pressure is about 100 mT and the second plasma chamber pressure is about 600 mT.

6. The method of claim 1 wherein igniting the plasma includes maintaining the first RF power and the first plasma chamber pressure for a predetermined duration.

7. The method of claim 6 wherein the predetermined duration is about 10 seconds.

8. The method of claim 1 further comprising detecting a plasma concentration in the plasma chamber, wherein igniting the plasma includes maintaining the first RF power and the first plasma chamber pressure until a predetermined plasma concentration in the plasma chamber is achieved.

9. The method of claim 1 further comprising detecting a plasma concentration in the plasma chamber, wherein maintaining the plasma includes maintaining the second RF power and the second plasma chamber pressure until the plasma concentration in the plasma chamber is less than a predetermined plasma concentration.

10. The method of claim 1 further comprising:
selecting a new plasma source gas;
repeating the igniting; and
resuming the maintaining.

11. A method, comprising:
transitioning a plasma chamber to a steady state when a first event occurs; and
transitioning the chamber to an ignition state when a second event occurs; wherein:
the ignition state employs a greater RF power than the steady state; and
the steady state employs a greater chamber pressure than the ignition state.

12. The method of claim 11 wherein the first event is the expiration of a predetermined time duration.

13. The method of claim 12 wherein the predetermined time duration is about 10 seconds.

14. The method of claim 11 wherein the first event is the transition of a plasma concentration within the chamber from less than a predetermined plasma concentration to greater than the predetermined plasma concentration.

15. The method of claim 11 wherein the second event is the transition of a plasma concentration within the chamber from greater than a predetermined plasma concentration to less than a predetermined plasma concentration.

16. The method of claim 11 wherein the second event is the selection of a new plasma source gas relative to that employed during any preceding state.

17. The method of claim 111 wherein the ignition state employs an RF power of about 20 W and the steady state employs an RF power of about 10 W.

18. The method of claim 11 wherein the ignition state employs a chamber pressure of about 100 mT and the steady state employs a chamber pressure of about 600 mT.

19. The method of claim 11 wherein the RF frequency during the ignition state and the steady state is about 13.56 MHz.

20. A system, comprising:
a plasma chamber;
a radio frequency (RF) power source coupled to a magnetic plasma igniting means that is disposed within the plasma chamber; and
a controller configured to operate the plasma chamber and the RF power source in an ignition state and a steady state, including increasing the plasma chamber's pressure and decreasing the RF power source's output when transitioning from the ignition state to the steady state.

21. The system of claim 20 wherein the controller is configured to transition operation of the plasma chamber and the RE power source from the ignition state to the steady state in response to the expiration of a predetermined time period.

22. The system of claim 20 further comprising a plasma sensor configured to detect existence of plasma within the plasma chamber, wherein the controller is configured to transition operation of the plasma chamber and the RF power source from the ignition state to the steady state in response to detection of plasma within the plasma chamber via the plasma sensor.

23. The system of claim 20 wherein the controller is configured to transition operation of the plasma chamber and the RF power source from the steady state to the ignition state in response to a plasma level within the plasma chamber falling below a minimum plasma level, as detected via the plasma sensor.
